(19) United States
(12) Patent Application Publication
(10) Pub. No.: US 2026/0285650 A1
(43) Pub. Date: Sep. 24, 2026

(54) OVERHEAD TRANSPORT VEHICLE SYSTEM AND OVERHEAD TRANSPORT VEHICLE

(71) Applicant: MURATA MACHINERY, LTD., Kyoto-shi, Kyoto (JP)

(72) Inventor: Makoto KOBAYASHI, Kyoto (JP)

(73) Assignee: MURATA MACHINERY, LTD., Kyoto-shi, Kyoto (JP)

(21) Appl. No.: 19/473,519

(22) PCT Filed: Mar. 6, 2024
(86) PCT No.: PCT/JP2024/008591

§ 371 Date: Oct. 8, 2025

(30) Foreign Application Priority Data
Apr. 10, 2023 (JP) 2023-063325

(51) Int. Cl. B66C 13/46; B66C 13/48; B66C 17/00

(52) U.S. Cl. CPC B66C 13/46; B66C 13/48; B66C 17/00

(57) ABSTRACT

Each transport vehicle in an overhead transport vehicle system includes a lifting member to feed out or wind in a belt connected to a gripper, a detector detecting that the gripper has reached a stop position for an article placed on a station, a memory that stores a teaching position set such that a distance from the stop position falls within a predetermined range, a transport vehicle control circuit that controls lowering of the gripper at a first speed and then at a second speed lower than the first speed from the teaching position and to stop the gripper when the detector detects that the gripper has reached the stop position, and a teaching position correction circuit configured to correct the feed amount of the belt stored for each station based on an actual stop position of the gripper at the time of transferring the article.

### TECHNICAL FIELD

An aspect of the present invention relates to an overhead transport vehicle system and an overhead transport vehicle.

### BACKGROUND ART

An overhead transport vehicle is known which travels on a track supported by a ceiling and transfers an article to a station. An overhead transport vehicle includes a gripping part that grips an article and a lifting part that raises and lowers the gripping part, and transfers the article to a station by lowering the gripping part. In such an overhead transport vehicle, an article is transferred to a station by lowering a gripping part based on a pre-stored set value. However, when the relative distance between the overhead transport vehicle and the station, or the controlled distance and the actual lowering distance change due to various factors (for example, when the height of the ceiling changes due to snow accumulation or the like, or when a belt or the like for suspending the gripping part is extended), there is a possibility that the article cannot be appropriately transferred, for example, the gripping part may crush the article or fail to grip the article.

As a technique for solving such a problem, for example, Patent Literature 1 discloses an overhead transport vehicle system including a laser distance sensor that detects a distance between an overhead transport vehicle and a station. In the overhead transport vehicle system described in Patent Literature 1, a set value is corrected based on a result of the detection by the laser distance sensor acquired at the time of transferring an article, and a gripping part is lowered based on the corrected set value.

### CITATION LIST

### Patent Literature

Patent Literature 1: Japanese Unexamined Patent Publication No. 2005-170554

### SUMMARY OF INVENTION

### Technical Problem

In addition, as a method for solving the above problem without the laser distance sensor, it is probable that the gripping part is lowered at a predetermined speed to a teaching position stored in advance, and the gripping part is lowered at a slow speed so that the gripping part can stop immediately after passing the teaching position. However, in this case, it is necessary to set a teaching position at an unnecessarily high position in order to appropriately transfer an article even when an unintended factor such as that described above occurs. It takes time for such an overhead transport vehicle to transfer an article to a station. Therefore, an object of an aspect of the present invention is to provide an overhead transport vehicle system and an overhead transport vehicle capable of appropriately transferring an article to a station in a short period of time even when a distance between a teaching position and a stop position changes due to various factors.

### Solution to Problem

An overhead transport vehicle system comprising a plurality of transport vehicles for transferring an article to a plurality of stations by raising and lowering a gripping part configured to grip the article with respect to a main part traveling on a track supported by a ceiling, in which each of the plurality of transport vehicles includes a detection unit provided in the gripping part, the detection unit configured to detect that the gripping part has reached a predetermined position with respect to the article placed on one of the plurality of stations, a lifting part configured to raise and lower the gripping part, a transport vehicle controller configured to lower the gripping part at a first speed with respect to the main part and then lower the gripping part at a second speed lower than the first speed from a teaching position stored in advance in a storage unit, and to transfer the article to one of the transport vehicles by stopping the gripping part when the detection unit detects that the gripping part has reached the predetermined position and a teaching position correction unit configured to correct the teaching position stored for each of the plurality of stations based on an actual stop position of the gripping part at a time of transferring the article.

An overhead transport vehicle for transferring an article to a plurality of stations by raising and lowering a gripping part configured to grip the article with respect to a main part traveling on a track supported by a ceiling, the overhead transport vehicle comprising a detection unit provided in the gripping part, the detection unit configured to detect that the gripping part has reached a predetermined position with respect to the article placed on one of the plurality of stations a lifting part configured to raise and lower the gripping part, a transport vehicle controller configured to lower the gripping part at a first speed with respect to the main part and then lower the gripping part at a second speed lower than the first speed from a teaching position stored in advance in a storage unit, and to transfer the article to one of the plurality of stations by stopping the gripping part when the detection unit detects that the gripping part has reached the predetermined position and a teaching position correction unit configured to correct the teaching position stored for each of the plurality of stations based on an actual stop position of the gripping part at a time of transferring the article.

In the overhead transport vehicle system and the overhead transport vehicle having this configuration, even when the positional relationship (distance) between the teaching position and the stop position is too short or too long due to various factors, the teaching position for each station is appropriately corrected based on the stop position at the time of transferring the article to the station. As a result, even if the distance between the teaching position and the stop position is unintentionally increased or decreased, the distance can be returned to an appropriate distance by the correction for the next transfer operation. As a result, the article can be appropriately transferred to the station in a short period of time even when the distance between the teaching position and the stop position changes due to various factors.

In the overhead transport vehicle system according to an aspect of the present invention, the storage unit associates and stores the teaching positions for each of the plurality of stations, and the teaching position correction unit may correct the teaching position based on the stop position acquired for every transfer operation by the plurality of transport vehicles. With this configuration, a correction value can be updated regardless of which transport vehicle transfers the article to the station. This allows the correction value to be updated frequently, which makes it possible to quickly respond to an unintended factor.

In the overhead transport vehicle system according to an aspect of the present invention, the storage unit associates and stores the teaching position corresponding to each of the plurality of transport vehicles for each of the plurality of stations, and the teaching position correction unit may correct the teaching position based on the stop position acquired by each of the transport vehicles for each of the plurality of stations. With this configuration, the positional relationship (distance) between the teaching position and the stop position is set between each station and each transport vehicle. This enables, for example, coping with a defect or the like caused by a factor due to a machine difference, such as elongation of a belt for suspending the gripping part.

In the overhead transport vehicle system according to an aspect of the present invention, the storage unit may be provided in each of the plurality of transport vehicles. With this configuration, the information (distance between the teaching position and the stop position) necessary for correcting the teaching position for each transport vehicle is stored in the subject vehicle and, thus, the amount of communication at the time of correcting the teaching position can be reduced.

### Advantageous Effects of Invention

According to an aspect of the present invention, it is possible to appropriately transfer an article to a station in a short period of time.

### BRIEF DESCRIPTION OF DRAWINGS

FIG. 1 is a side view of an overhead transport vehicle according to the present embodiment.

FIG. 2 is a side view for a case where the overhead transport vehicle of FIG. 1 lowers a gripping part.

FIG. 3 is a front view illustrating a relationship between a teaching position and a stop position.

FIG. 4 is a functional block diagram illustrating a functional configuration of the overhead transport vehicle of FIG. 1.

FIG. 5 is a V-T graph for a case where a lifting part descends.

FIG. 6 is a flowchart illustrating a flow of correction to a teaching position by an overhead transport vehicle system of FIG. 1.

FIG. 7 is a flowchart illustrating a flow of correction to a teaching position, which is continued from FIG. 6.

FIG. 8(A) illustrates an example of a data configuration stored in a teaching position storage unit of an area controller. FIG. 8(B) illustrates an example of a data configuration stored in a teaching position storage unit of a first vehicle according to a first modification. FIG. 8(C) illustrates an example of a data configuration stored in a teaching position storage unit of a second vehicle according to the first modification. FIG. 8(D) illustrates an example of a data configuration stored in a teaching position storage unit of an area controller according to a second modification.

FIG. 9 is a flowchart illustrating a flow of correction to a teaching position by an overhead transport vehicle system according to a modification.

FIG. 10 is a flowchart illustrating a flow of correction to a teaching position, which is continued from FIG. 9.

FIG. 11 is a flowchart illustrating a flow of correction to a teaching position by an overhead transport vehicle system according to a further modification.

### DESCRIPTION OF EMBODIMENTS

Hereinafter, an overhead transport vehicle system 80 according to an embodiment will be described with reference to the drawings. In description of the drawings, the same elements are denoted by the same reference numerals, and redundant description will be omitted.

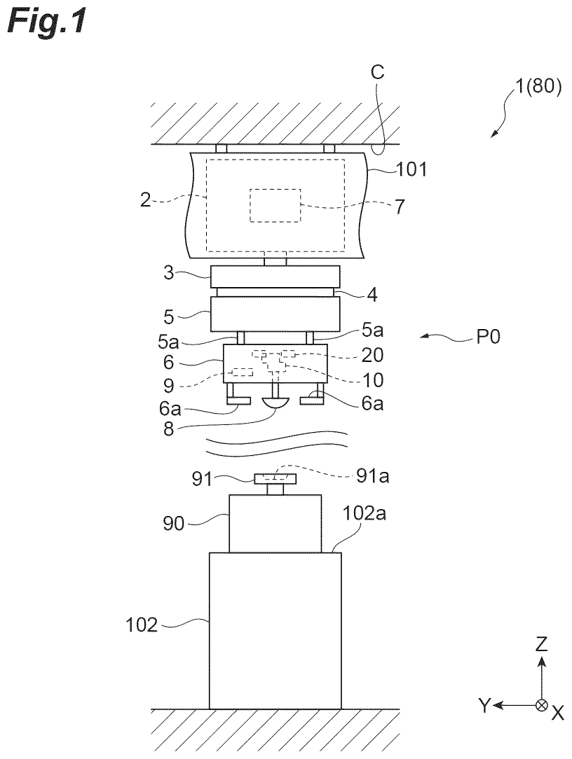

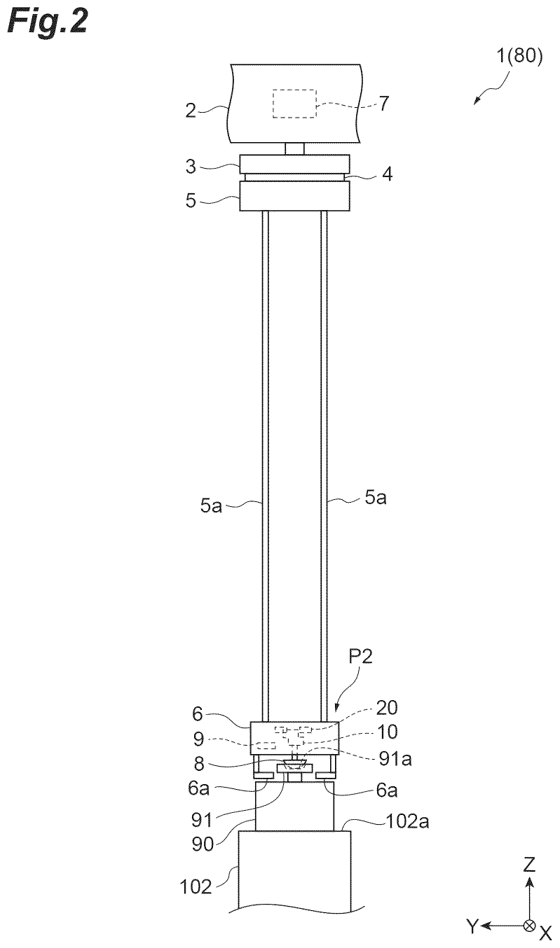

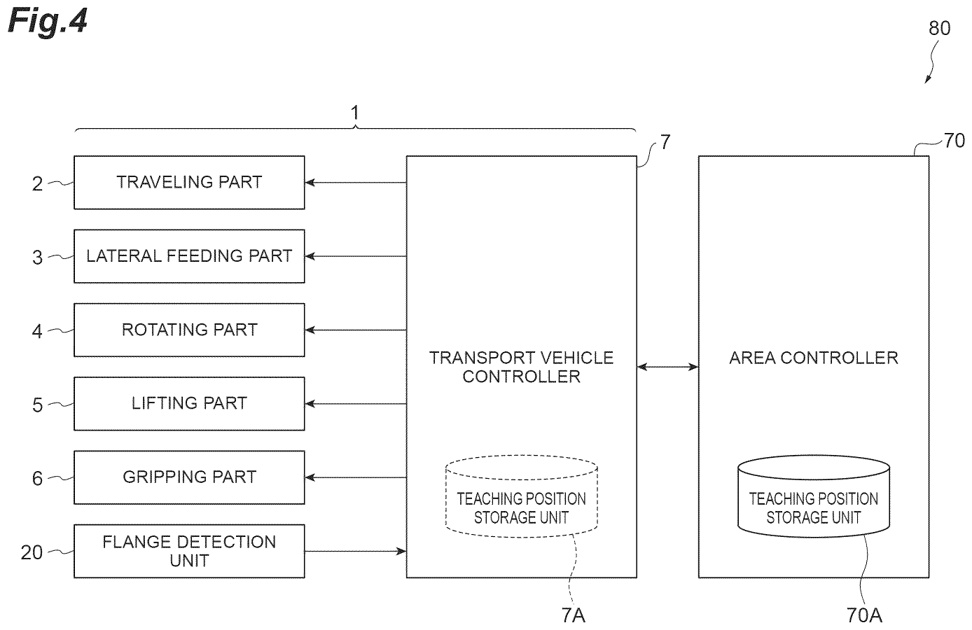

As illustrated in FIGS. 1 and 2, the overhead transport vehicle system 80 includes a plurality of overhead transport vehicles 1 (hereinafter, each is simply referred to as a “transport vehicle 1”), a plurality of load ports 102, and an area controller (teaching position correction unit) 70 (see FIG. 4).

The transport vehicle 1 travels along a travel rail (track) 101 laid near a ceiling C of a clean room in which semiconductor devices are manufactured. The transport vehicle 1 transports a FOUP (article) 90 which is a container containing a plurality of semiconductor wafers. The transport vehicle 1 transfers the FOUP 90 to a load port (station) 102 provided in a processing device that performs various processes on a semiconductor wafer. That is, the transport vehicle 1 retrieves the FOUP 90 placed on a placement surface 102a of the load port 102, and places the FOUP 90 on the placement surface 102a of the load port 102.

The transport vehicle 1 includes a traveling part 2, a lateral feeding part 3, a turning part 4, a lifting part 5, a gripping part 6, and a transport vehicle controller (teaching position correction unit) 7. The traveling part 2 is supplied with power in a non-contact manner from a high-frequency current line laid along the travel rail 101 to thereby travel along the travel rail 101, for example. The lateral feeding part 3 moves the turning part 4, the lifting part 5, and the gripping part 6 in the transverse direction with respect to the direction in which the travel rail 101 extends. The turning part 4 rotates the lifting part 5 and the gripping part 6 in a horizontal plane. The lifting part 5 includes a plurality of belts 5a, and the gripping part 6 is attached to lower ends of the belts 5a.

The lifting part 5 raises and lowers the gripping part 6 by feeding or winding the plurality of belts (suspending members) 5a. The gripping part 6 grips a flange portion 91 of the FOUP 90 by closing a pair of claw members 6a. The gripping part 6 releases the gripped state of the flange portion 91 by opening the pair of claw members 6a.

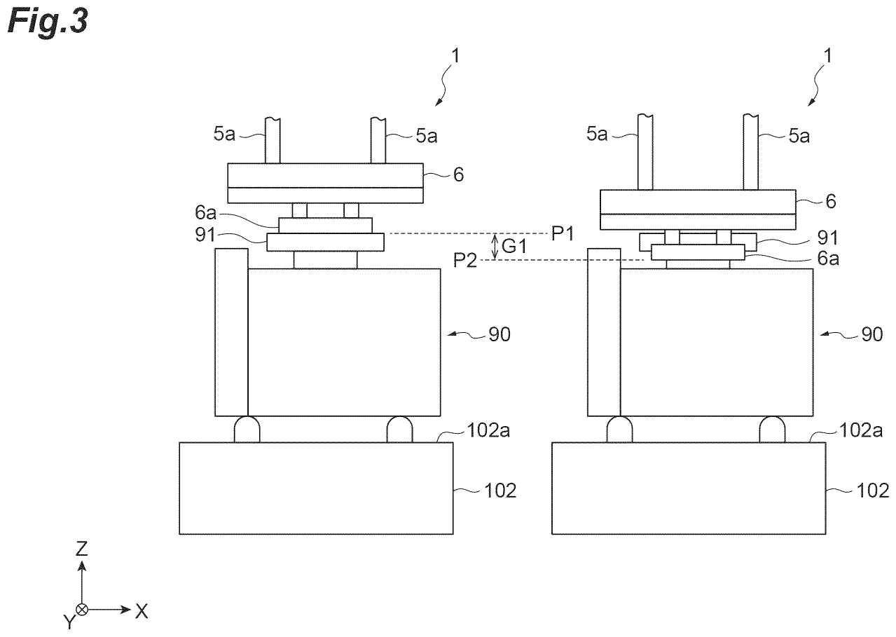

In FIG. 1, the X, Y, and Z axes are also illustrated. A Y direction in the drawing is a travel direction of the overhead transport vehicle 1, and an X direction in the drawing is a lateral movement direction in which the gripping part 6 and the like are moved by the lateral feeding part 3. A Z direction in the drawing is a vertical direction. The overhead transport vehicle 1 lowers the gripping part 6 along the Z direction and raises the gripping part 6 along the Z direction. The travel direction (Y direction) of the overhead transport vehicle 1, the lateral movement direction (X direction) by the lateral feeding part 3, and the vertical direction (Z direction) are orthogonal to each other. Similarly, the X, Y, and Z axes are illustrated also in FIGS. 2 and 3, which are referred to in the following description.

As illustrated in FIGS. 1 and 2, the transport vehicle 1 further includes a center cone 8, a dog 10, and a flange detection unit (detection unit) 20. A recess 91a that is open upward is formed at the center of the flange portion 91 of the FOUP 90. The center cone 8 is a member that is to be fitted into the recess 9 la of the flange portion 91 to position the gripping part 6 with respect to the FOUP 90. The center cone 8, the dog 10, and the flange detection unit 20 are provided in the gripping part 6. The center cone 8, the dog 10, and the flange detection unit 20 are attached to a base portion (not illustrated) of the gripping part 6. The center cone 8 is biased downward by a spring (not illustrated) attached to the base portion, and is freely movable up and down with respect to the gripping part 6.

As illustrated in FIGS. 1, 2, and 4, the transport vehicle controller 7 is a unit that controls the operation of each part in the transport vehicle 1, and includes a central processing unit (CPU), a read only memory (ROM), and a random access memory (RAM). The transport vehicle controller 7 may be configured as hardware.

Hereinafter, the transfer operation in the transport vehicle 1 will be described. In order to grip the FOUP 90 placed on the load port 102, the transport vehicle controller 7 controls the gripping part 6 to descend, which allows the center cone 8 to be fitted into the recess 91a of the flange portion 91. When the gripping part 6 further descends, the center cone 8 rises relative to the gripping part 6. The transport vehicle controller 7 detects that the gripping part 6 has reached a gripping position (stop position P2) (see FIGS. 2 and 3) by a photointerrupter including a light projecting portion and a light receiving portion of the flange detection unit 20 and a light shielding plate portion of the dog 10 passing on the optical axis of the photointerrupter. That is, it can be said that the center cone 8, the dog 10, and the flange detection unit 20 are provided in the gripping part 6 and constitute a contact sensor that detects contact with the FOUP 90. When detecting that the gripping part 6 has reached the gripping position, the transport vehicle controller 7 stops the descent of the gripping part 6.

The transport vehicle controller 7 causes the gripping part 6 to close the pair of claw members 6a. As the claw members 6a are closed, the claw members 6a enter under the flange portion 91. The transport vehicle controller 7 then controls the lifting part 5 to start raising the gripping part 6. When the gripping part 6 holding the FOUP 90 places the FOUP 90 on the placement surface 102a of the load port 102, that is, when unloading, the operation is the reverse of the operation at the time of gripping.

The flange detection unit 20 detects that the gripping part 6 has reached a predetermined position with respect to the FOUP 90 placed on the load port 102. The recognition of the position of the gripping part 6 using the center cone 8, the dog 10, and the flange detection unit 20 and the recognition of the state in which the FOUP 90 is gripped by the gripping part 6 are implemented by using, for example, the configuration and method described in Patent Literature 1 (International Publication No. 2018/179931). However, the position of the gripping part 6 and the state in which the FOUP 90 is gripped by the gripping part 6 may be recognized by using other known configurations and methods.

The lifting part 5 includes a lifting motor (not illustrated), and the lifting motor unwinds the belt 5a to lower the gripping part 6, and the lifting motor winds up the belt 5a to raise the gripping part 6. The lifting motor is driven and controlled by the transport vehicle controller 7. The transport vehicle controller 7 can detect the amount of the belt 5a unwound (belt length) by receiving a signal related to the rotation from the lifting motor. The transport vehicle controller 7 can position the gripping part 6 at any position in the vertical direction based on the amount of the belt 5a unwound (belt length). In the present embodiment, the transport vehicle controller 7 positions the gripping part 6 at a teaching position P1 based on the amount of the belt 5a unwound (belt length). In addition, the transport vehicle controller 7 can acquire the position (height position) of the gripping part 6 at the stop position P2 (gripping position at which to grip the FOUP 90) based on the amount of the belt 5a unwound.

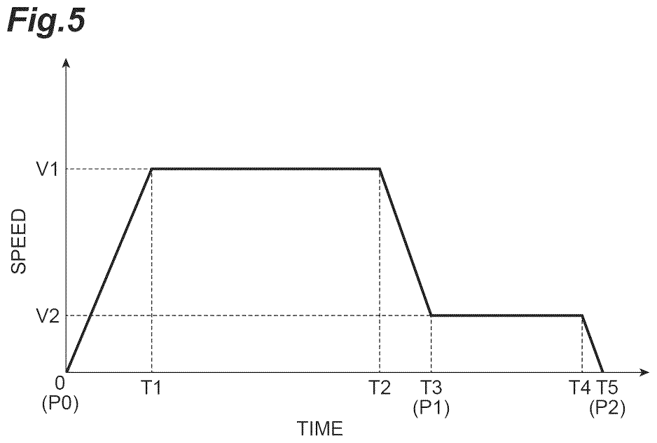

As illustrated in FIGS. 3 and 5, in order to transfer the FOUP 90 to the load port 102, the transport vehicle controller 7 lowers the gripping part 6 with respect to the traveling part (main part) 2 at a first speed V1, then lowers the gripping part 6 from the teaching position P1 that is stored in advance, at a second speed V2 lower than the first speed V1, and stops the gripping part 6 in response to the flange detection unit 20 detecting the FOUP 90. More specifically, the transport vehicle controller 7 controls the lifting part 5 so that the gripping part 6 descends at the first speed V1 from a traveling time position P0, which is the position of the gripping part 6 when the transport vehicle 1 travels.

Next, the transport vehicle controller 7 controls the lifting part 5 so that the gripping part 6 descends from the teaching position P1 at the second speed V2. The second speed V2 is, for example, a speed at which the gripping part 6 can stop at a relatively short distance (for example, 5 mm) when the lifting part 5 is controlled to stop. When the flange detection unit 20 detects the FOUP 90 (that is, detects that the gripping part 6 has reached the predetermined position with respect to the FOUP 90 placed on the load port 102), the transport vehicle controller 7 controls the lifting part 5 to stop the descent of the gripping part 6.

Under such control by the transport vehicle controller 7, when the transport vehicle 1 transfers the FOUP 90 to the load port 102, the gripping part 6 is initially lowered at a high speed, and then the gripping part 6 is lowered at a low speed after the teaching position close to the FOUP 90. This shortens the time necessary for the gripping part 6 to descend to the teaching position and then the gripping part 6 is lowered slowly to thereby reduce the impact when the FOUP 90 is placed on the load port 102 and to prevent the gripping part 6 from colliding with the flange portion 91 of the FOUP 90 when the gripping part 6 grips the FOUP 90 placed on the load port 102. Such a teaching position is so set that the distance between the teaching position and the stop position P2 falls within a predetermined range. The teaching position is stored by the transport vehicle controller 7 as the teaching position P1, and the initial value of the teaching position P1 is appropriately set when the overhead transport vehicle system 80 is installed or the like.

The transport vehicle controller 7 corrects the teaching position P1 stored for each of the plurality of load ports 102 based on the actual stop position P2 of the gripping part 6 at the time of transferring the FOUP 90. Specifically, the area controller 70 determines whether a difference in distance between the teaching position P1 and the stop position P2 falls within a predetermined range (for example, within ±5 mm). When determining that the distance difference is not within the predetermined range, the area controller 70 calculates a correction value for the teaching position P1 based on the stop position P2. The correction value is, for example, a shift amount with respect to the teaching position P1, and is an amount indicating how much the teaching position P1 needs to be shifted from the teaching position P1 so that a distance to the stop position P2 falls within the predetermined range. The transport vehicle controller 7 transmits the correction value for the teaching position P1 calculated in this manner to the area controller 70. In a case where the transport vehicle controller 7 can acquire the correction value for the teaching position P1 from the area controller 70 at the time of transfer, the transport vehicle controller 7 determines whether a difference in distance between the teaching position P1 and the stop position P2 in consideration of the correction value falls within the predetermined range, and in a case where the transport vehicle controller 7 determines that the distance difference does not fall within the predetermined range, a correction value for the teaching position P1 based on the stop position P2 is calculated.

The area controller 70 includes a CPU, a ROM, and a RAM. The area controller 70 can be configured, for example, as software in which a program stored in the ROM is loaded into the RAM and executed by the CPU. The area controller 70 may be configured as hardware with electronic circuit or the like. The area controller 70 transmits, for example, a transport command for causing the transport vehicle 1 to transport the FOUP 90. The area controller 70 is provided so as to be able to communicate with the transport vehicle 1 via a power feeding unit or the like disposed on the travel rail 101.

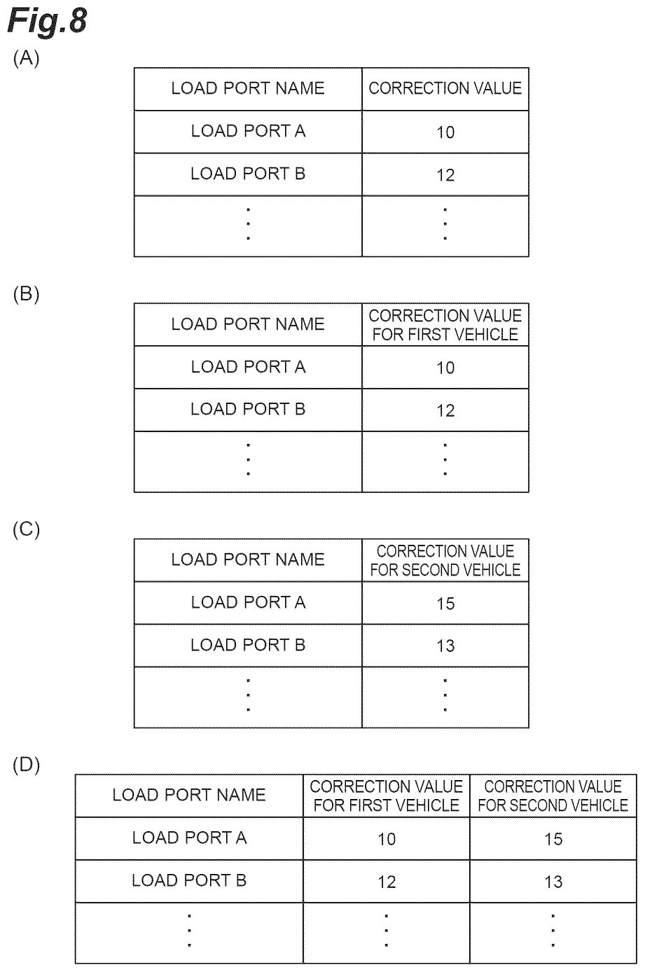

The area controller 70 includes a teaching position storage unit 70A that stores information on the teaching position P1. The teaching position storage unit 70A is a storage such as a hard disk drive (HDD) or a solid state drive (SSD). As illustrated in FIG. 8(A), the teaching position storage unit 70A associates and stores a correction value for one teaching position P1 for each of the plurality of load ports 102 provided in the overhead transport vehicle system 80.

The area controller 70 stores the correction values for the teaching position P1 transmitted from the plurality of transport vehicles 1 in the teaching position storage unit 70A. In a case where no correction value for the teaching position P1 is stored in the teaching position storage unit 70A, the area controller 70 newly stores the correction value for the teaching position P1 transmitted. In a case where the correction value for the teaching position P1 is already stored, the area controller 70 overwrites (updates) it with the transmitted correction value for the teaching position P1. It can be said that the area controller 70 of the present embodiment corrects the teaching position P1 based on the stop position P2 acquired every time the plurality of transport vehicles 1 performs transfer operation. That is, in the present embodiment, the teaching position P1 with respect to one load port 102 can be corrected by the transfer operation of each of the plurality of transport vehicles 1.

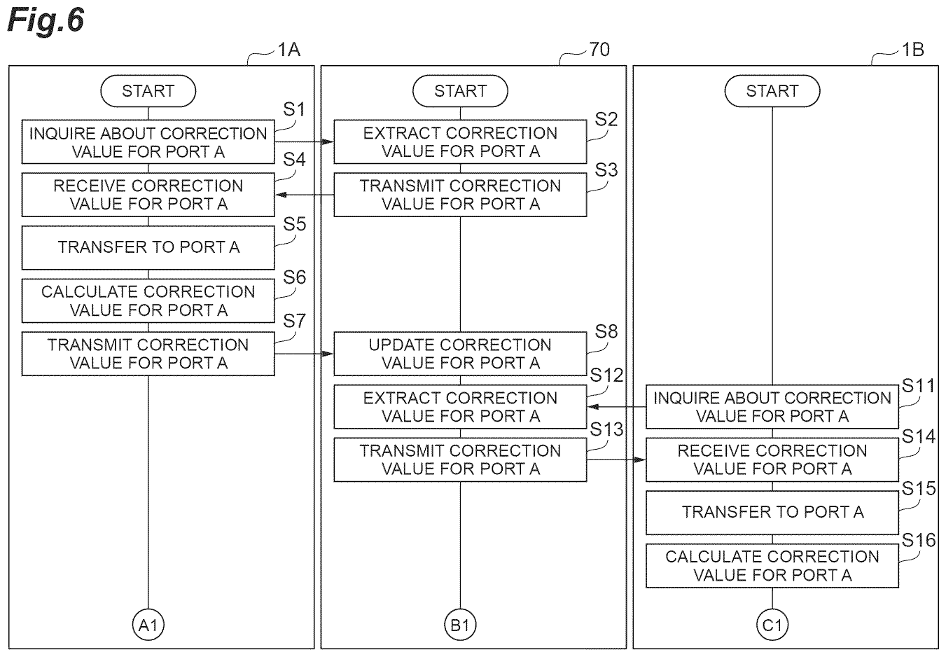

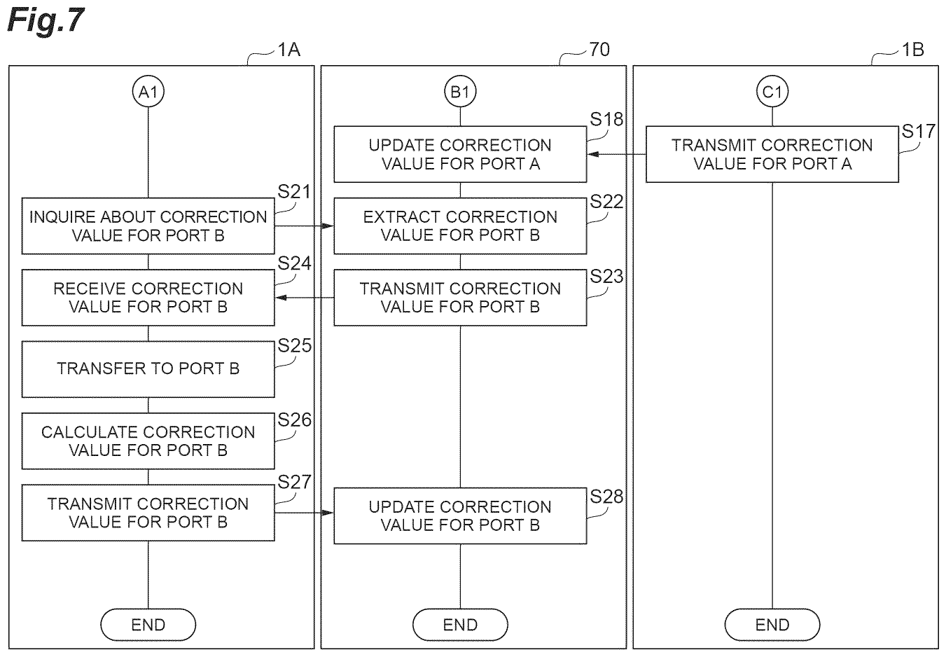

The correction to the teaching position P1 executed by the area controller 70 in the overhead transport vehicle system 80 described above will be described with reference to the flowcharts of FIGS. 6 and 7. Here, as an example, a case where the teaching position P1 is corrected by two transport vehicles 1 and 1 of the plurality of transport vehicles 1 and the correction value is already stored in the teaching position storage unit 70A of the area controller 70 will be described. For ease of explanation, the two transport vehicles 1 and 1 are referred to as a first vehicle 1A and a second vehicle 1B.

As illustrated in FIG. 6, when the first vehicle 1A transfers the FOUP 90 to a load port A which is one of the plurality of load ports 102 (hereinafter, simply referred to as a “port A”), the transport vehicle controller 7 of the first vehicle 1A inquires of the area controller 70 about a correction value for the teaching position P1 of the port A (hereinafter, referred to as a “correction value for the port A”) (Step S1). The area controller 70 that has received the inquiry extracts the correction value for the port A from the teaching position storage unit 70A (Step S2), and transmits the correction value for the port A to the transport vehicle controller 7 of the first vehicle 1A (Step S3). The transport vehicle controller 7 of the first vehicle 1A receives the correction value for the port A transmitted from the area controller 70 (Step S4).

The transport vehicle controller 7 of the first vehicle 1A transfers the FOUP 90 to the port A based on the teaching position P1 stored in advance and the correction value for the port A (Step S5). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port A) for correcting the teaching position P1 to fall within the predetermined range based on the stop position P2 (Step S6). The transport vehicle controller 7 of the first vehicle 1A transmits the correction value for the port A calculated in this manner to the area controller 70 (Step S7). The area controller 70 causes the teaching position storage unit 70A to store (update) the correction value for the port A received from the first vehicle 1A (Step S8). Specifically, the area controller 70 updates the database as illustrated in FIG. 8(A).

When the second vehicle 1B transfers the FOUP 90 to the port A, the transport vehicle controller 7 of the second vehicle 1B inquires of the area controller 70 about the correction value for the port A (Step S11). The area controller 70 that has received the inquiry extracts the correction value for the port A from the teaching position storage unit 70A (Step S12), and transmits the correction value for the port A to the transport vehicle controller 7 of the second vehicle 1B (Step S13). The transport vehicle controller 7 of the second vehicle 1B receives the correction value for the port A transmitted from the area controller 70 (Step S14).

The transport vehicle controller 7 of the second vehicle 1B transfers the FOUP 90 to the port A based on the teaching position P1 stored in advance and the correction value for the port A (Step S15). The transport vehicle controller 7 of the second vehicle 1B determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the second vehicle 1B calculates a correction value (correction value for the port A) for correcting the teaching position P1 to fall within the predetermined range based on the stop position P2 (Step S16). As illustrated in FIG. 7, the transport vehicle controller 7 of the second vehicle 1B transmits the correction value for the port A calculated in this manner to the area controller 70 (Step S17). The area controller 70 causes the teaching position storage unit 70A to store (update) the correction value for the port A received from the second vehicle 1B (Step S18). Specifically, the area controller 70 updates the database as illustrated in FIG. 8(A).

Incidentally, the transport vehicle 1 other than the first vehicle 1A and the second vehicle 1B can also calculate the correction value for the port A by the same method and transmit the correction value to the area controller 70. The area controller 70 can cause the teaching position storage unit 70A to store (update) the correction value for the port A received from the transport vehicle 1 other than the first vehicle 1A and the second vehicle 1B.

When the first vehicle 1A transfers the FOUP 90 to a load port B which is one of the plurality of load ports 102 (hereinafter, simply referred to as a “port B”), the transport vehicle controller 7 of the first vehicle 1A inquires of the area controller 70 about a correction value for the port B (Step S21). The area controller 70 that has received the inquiry extracts the correction value for the port B from the teaching position storage unit 70A (Step S22), and transmits the correction value for the port B to the transport vehicle controller 7 of the first vehicle 1A (Step S23). The transport vehicle controller 7 of the first vehicle 1A receives the correction value for the port B transmitted from the area controller 70 (Step S24).

The transport vehicle controller 7 of the first vehicle 1A transfers the FOUP 90 to the port B based on the teaching position P1 stored in advance and the correction value for the port B (Step S25). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port B) for correcting the teaching position P1 to fall within the predetermined range based on the stop position P2 (Step S26). The transport vehicle controller 7 of the first vehicle 1A transmits the correction value for the port B calculated in this manner to the area controller 70 (Step S27). The area controller 70 causes the teaching position storage unit 70A to store (update) the correction value for the port B received from the first vehicle 1A (Step S28). Specifically, the area controller 70 updates the database as illustrated in FIG. 8(A).

Incidentally, the transport vehicle 1 other than the first vehicle 1A can also calculate the correction value for the port B by the same method and transmit the correction value to the area controller 70. The area controller 70 can cause the teaching position storage unit 70A to store (update) the correction value for the port B received from the transport vehicle 1 other than the first vehicle 1A. Specifically, the area controller 70 updates the database as illustrated in FIG. 8(A).

Functions and effects of the overhead transport vehicle system 80 according to the above embodiment will be described. In the overhead transport vehicle system 80 of the above embodiment, the gripping part 6 is lowered at a high speed in a section where the possibility of collision is low, and is lowered at a low speed in a section where the possibility of collision is high. The start point of the section where the possibility of collision is high is stored in advance as the teaching position P1, and the positional relationship (distance) between the teaching position P1 and the stop position P2 may be unintentionally too short or too long due to the factors described above. In a case where the positional relationship is unintentionally too short, the FOUP 90 cannot be appropriately transferred to the load port 102. In a case where the positional relationship is unintentionally too long, it takes time to transfer the FOUP 90 to the load port 102. In this regard, in the overhead transport vehicle system 80 of the above embodiment, the teaching position P1 for each load port 102 is appropriately corrected based on the stop position P2 at the time of transfer to the load port 102. As a result, even if the distance between the teaching position P1 and the stop position P2 is unintentionally increased or decreased, the distance can be returned to an appropriate distance by the correction, which enables the FOUP 90 to be transferred appropriately to the load port 102 in a short period of time.

In the overhead transport vehicle system 80 of the above embodiment, the teaching position storage unit 70A associates and stores one teaching position P1 for each of the plurality of load ports 102, and the area controller 70 corrects the teaching position P1 based on the stop position P2 acquired for every transfer operation by the plurality of transport vehicles 1. As a result, the correction value can be updated regardless of which transport vehicle 1 transfers the FOUP 90 to the load port 102. This allows the correction value to be updated frequently, which makes it possible to quickly respond to an unintended factor.

Although one embodiment has been described above, one aspect of the present invention is not limited to the above embodiment. Various modifications can be made without departing from the gist of the invention.

### First Modification

In the above embodiment, an example has been described in which the teaching position storage unit 70A associates and stores one teaching position P1 for each of the plurality of load ports 102, and the area controller 70 corrects the teaching position P1 based on the stop position P2 acquired for every transfer operation by the plurality of transport vehicles 1, but the present invention is not limited thereto.

In the transport vehicle 1 according to the first modification, a teaching position storage unit 7A may be provided in the transport vehicle controller 7 instead of the area controller 70. The teaching position storage unit 70A is a storage such as a hard disk drive (HDD) or a solid state drive (SSD). The teaching position storage unit 7A is a storage such as a hard disk drive (HDD) or a solid state drive (SSD). The teaching position storage unit 7A is provided for each transport vehicle 1, and associates and stores the teaching position P1 corresponding to each of the plurality of transport vehicles 1 for each of the plurality of load ports 102 as illustrated in FIGS. 8(B) and 8(C). The transport vehicle controller 7 corrects, for each of the plurality of load ports 102, the teaching position P1 based on the stop position P2 acquired by each transport vehicle 1.

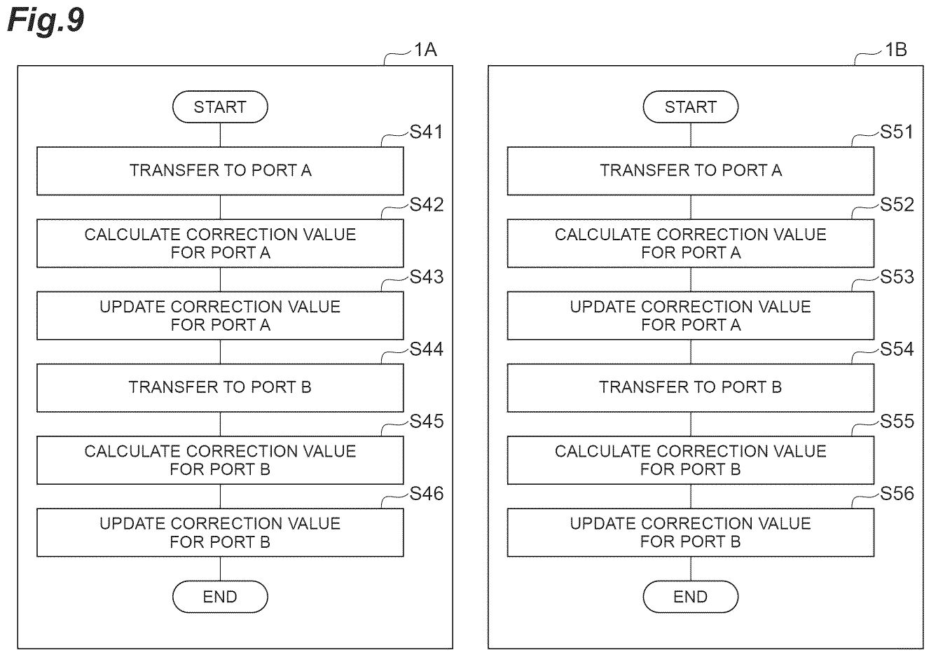

The correction to the teaching position P1 executed by the transport vehicle controller 7 in the transport vehicle 1 according to the first modification will be described with reference to the flowchart of FIG. 9. Here, as an example, a case where each of the two transport vehicles 1 and 1 of the plurality of transport vehicles 1 corrects the teaching position P1 using the transport vehicle controller 7 of the subject vehicle and a case where the correction value is already stored in the teaching position storage unit 7A of the transport vehicle controller 7 of each transport vehicle 1 will be described. Here again, for ease of explanation, the two transport vehicles 1 and 1 are referred to as a first vehicle 1A and a second vehicle 1B.

The first vehicle LA transfers the FOUP 90 to the port A. The transport vehicle controller 7 of the first vehicle 1A transfers the FOUP 90 to the port A based on the teaching position P1 stored in advance and the correction value for the port A (Step S41). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port A) for correcting the teaching position P1 to fall within the predetermined range based on the stop position P2 (Step S42). The transport vehicle controller 7 of the first vehicle 1A causes the teaching position storage unit 7A to store (update) the correction value for the port A calculated as described above (Step S43). Specifically, the transport vehicle controller 7 updates the database as illustrated in FIG. 8(B).

Next, the first vehicle 1A transfers the FOUP 90 to the port B. The transport vehicle controller 7 of the first vehicle 1A transfers the FOUP 90 to the port B based on the teaching position P1 stored in advance and the correction value for the port B (Step S44). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port B) for correcting the teaching position P1 to fall within the predetermined range based on the stop position P2 (Step S45). The transport vehicle controller 7 of the first vehicle 1A causes the teaching position storage unit 7A to store (update) the correction value for the port B calculated as described above (Step S46). Specifically, the transport vehicle controller 7 updates the database as illustrated in FIG. 8(B).

Similarly to the first vehicle 1A, Steps S51 to S53 illustrated in FIG. 9 are executed for the second vehicle 1B to cause the teaching position storage unit 7A included in the transport vehicle controller 7 of the subject vehicle to store (update) the correction value for the port A. Steps S54 to S56 illustrated in FIG. 9 are executed for the second vehicle 1B to cause the teaching position storage unit 7A to store (update) the correction value for the port B. In these cases, the transport vehicle controller 7 updates the database as illustrated in FIG. 8(C).

In the transport vehicle 1 according to the first modification, the positional relationship (distance) between the teaching position P1 and the stop position P2 is set between each load port 102 and each transport vehicle 1. This enables, for example, coping with a defect or the like caused by a factor due to a machine difference, such as elongation of the belt 5a for suspending the gripping part 6. Further, in the transport vehicle 1 according to the first modification, the teaching position P1 is corrected for each transport vehicle 1 and, thus, the communication amount at the time of correcting the teaching position P1 can be reduced.

### Second Modification

In the transport vehicle 1 according to the first modification, an example has been described in which the transport vehicle controller 7 provided in each transport vehicle 1 corrects the teaching position P1 and causes the teaching position storage unit 7A provided in the transport vehicle controller 7 of each transport vehicle 1 to store the correction value, but the present invention is not limited thereto. In the overhead transport vehicle system 80 according to the second modification, the transport vehicle controller 7 of each transport vehicle 1 calculates a correction value for each port based on the stop position P2 acquired at the time of transfer and transmits the correction value to the area controller 70, and the area controller 70 causes the teaching position storage unit 70A to store (update), for each transport vehicle, the correction value for each port acquired from the transport vehicle controller 7.

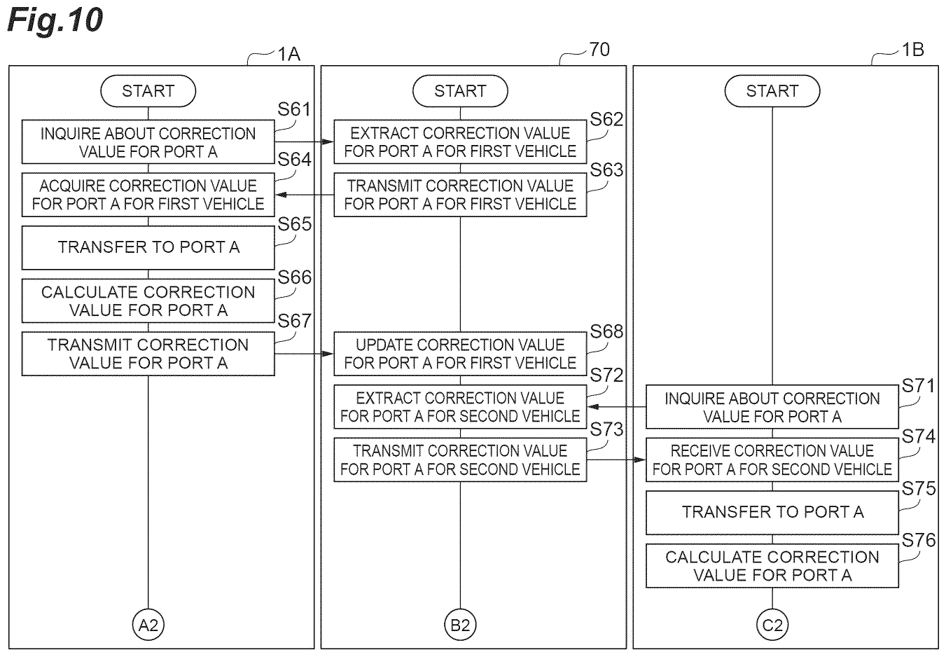

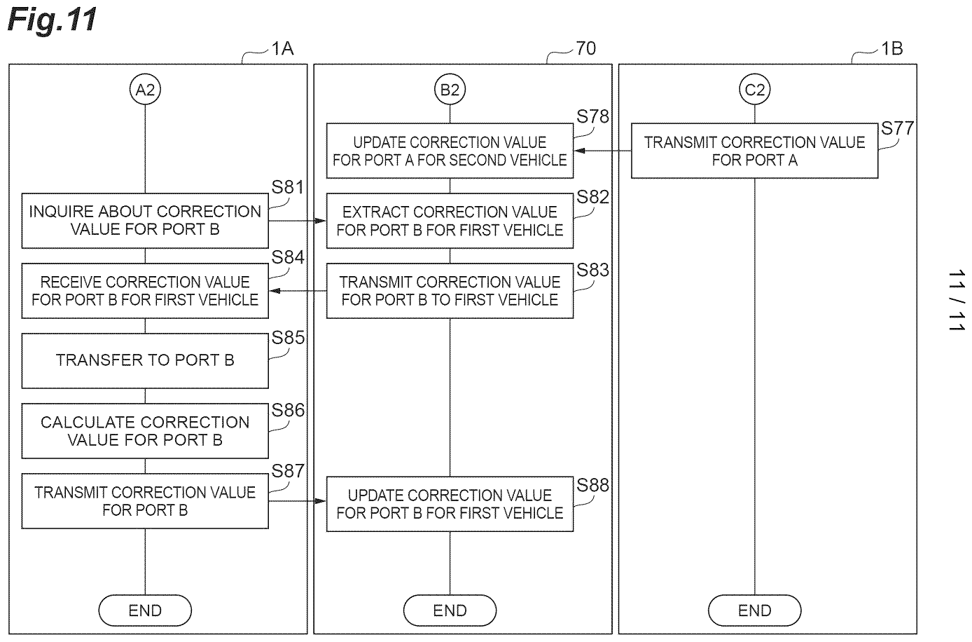

The correction to the teaching position P1 executed by the area controller 70 in the overhead transport vehicle system 80 according to the second modification will be described with reference to the flowcharts of FIGS. 10 and 11. Here, as an example, a case where the teaching position P1 is corrected by two transport vehicles 1 and 1 of the plurality of transport vehicles 1 and a case where the correction value is already stored in the teaching position storage unit 7A of the transport vehicle controller 7 for each transport vehicle 1 will be described. For ease of explanation, the two transport vehicles 1 and 1 are referred to as a first vehicle 1A and a second vehicle 1B.

As illustrated in FIG. 10, when the first vehicle 1A transfers the FOUP 90 to the port A, the transport vehicle controller 7 of the first vehicle 1A inquires of the area controller 70 about the correction value for the port A (Step S61). The area controller 70 that has received the inquiry extracts the correction value for the port A for the first vehicle 1A from the teaching position storage unit 70A (Step S62), and transmits the correction value for the port A for the first vehicle 1A to the transport vehicle controller 7 of the first vehicle 1A (Step S63). The transport vehicle controller 7 of the first vehicle 1A receives the correction value for the port A for the first vehicle 1A transmitted from the area controller 70 (Step S64).

The transport vehicle controller 7 of the first vehicle LA transfers the FOUP 90 to the port A based on the teaching position P1 stored in advance and the correction value for the port A (Step S65). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port A) for correcting the teaching position P1 to fall within the predetermined range based on the stop position P2 (Step S66). The transport vehicle controller 7 of the first vehicle 1A transmits the correction value for the port A calculated in this manner to the area controller 70 (Step S67). The area controller 70 causes the teaching position storage unit 70A to store (update) the correction value for the port A received from the first vehicle 1A as the correction value for the port A for the first vehicle 1A (Step S68). Specifically, the area controller 70 updates the database as illustrated in FIG. 8(D).

When the second vehicle 1B transfers the FOUP 90 to the port A, the transport vehicle controller 7 of the second vehicle 1B inquires of the area controller 70 about the correction value for the port A (Step S71). The area controller 70 that has received the inquiry extracts the correction value for the port A for the second vehicle 1B from the teaching position storage unit 70A (Step S72), and transmits the correction value for the port A for the second vehicle 1B to the transport vehicle controller 7 of the second vehicle 1B (Step S73). The transport vehicle controller 7 of the second vehicle 1B receives the correction value for the port A for the second vehicle 1B transmitted from the area controller 70 (Step S74).

The transport vehicle controller 7 of the second vehicle 1B transfers the FOUP 90 to the port A based on the teaching position P1 stored in advance and the correction value for the port A (Step S75). The transport vehicle controller 7 of the second vehicle 1B determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the second vehicle 1B calculates a correction value (correction value for the port A) for correcting the teaching position P1 to fall within the predetermined range based on the stop position P2 (Step S76). As illustrated in FIG. 11, the transport vehicle controller 7 of the second vehicle 1B transmits the correction value for the port A calculated in this manner to the area controller 70 (Step S77). The area controller 70 causes the teaching position storage unit 70A to store (update) the correction value for the port A received from the second vehicle 1B as the correction value for the port A for the second vehicle 1B (Step S78). Specifically, the area controller 70 updates the database as illustrated in FIG. 8(D).

Incidentally, the transport vehicle 1 other than the first vehicle 1A and the second vehicle 1B can also calculate the correction value for the port A by the same method and transmit the correction value to the area controller 70. The area controller 70 can cause the teaching position storage unit 70A to store (update) the correction value for the port A received from the transport vehicle 1 other than the first vehicle 1A and the second vehicle 1B as the correction value for the port A for each transport vehicle 1.

When the first vehicle 1A transfers the FOUP 90 to the port B, the transport vehicle controller 7 of the first vehicle 1A inquires of the area controller 70 about the correction value for the port B (Step S81). The area controller 70 that has received the inquiry extracts the correction value for the port B for the first vehicle 1A from the teaching position storage unit 70A (Step S82), and transmits the correction value for the port B for the first vehicle 1A to the transport vehicle controller 7 of the first vehicle 1A (Step S83). The transport vehicle controller 7 of the first vehicle 1A receives the correction value for the correction value for the port B for the first vehicle LA transmitted from the area controller 70 (Step S84).

The transport vehicle controller 7 of the first vehicle 1A transfers the FOUP 90 to the port B based on the teaching position P1 stored in advance and the correction value for the port B (Step S85). The transport vehicle controller 7 of the first vehicle 1A determines whether a difference between the stop position P2 at the time of transfer in this case and the teaching position P1 in consideration of the correction value falls within a predetermined range. Then, in a case where determining that the difference does not fall within the predetermined range, the transport vehicle controller 7 of the first vehicle 1A calculates a correction value (correction value for the port B) for correcting the teaching position P1 to fall within the predetermined range based on the stop position P2 (Step S86). The transport vehicle controller 7 of the first vehicle 1A transmits the correction value for the port B calculated in this manner to the area controller 70 (Step S87). The area controller 70 causes the teaching position storage unit 70A to store (update) the correction value for the port B received from the first vehicle 1A as the correction value for the port B for the first vehicle 1A (Step S88). Specifically, the area controller 70 updates the database as illustrated in FIG. 8(D).

Incidentally, the transport vehicle 1 other than the first vehicle 1A can also calculate the correction value for the port B by the same method and transmit the correction value to the area controller 70. The area controller 70 can cause the teaching position storage unit 70A to store (update) the correction value for the port B received from the transport vehicle 1 other than the first vehicle 1A as the correction value for the port B for each transport vehicle 1. Specifically, the area controller 70 updates the database as illustrated in FIG. 8(D).

In the transport vehicle 1 according to the second modification, the positional relationship (distance) between the teaching position P1 and the stop position P2 is set between each load port 102 and each transport vehicle 1. This enables, for example, coping with a defect or the like caused by a factor due to a machine difference, such as elongation of the belt 5a for suspending the gripping part 6.

### Other Modifications

In the embodiment and the second modification, an example in which the transport vehicle controller 7 calculates the correction values for the port A and the port B has been described. However, a configuration is possible in which the transport vehicle controller 7 transmits only information related to the stop position P2 and the area controller 70 calculates the correction values for the port A and the port B. The method of calculating the correction values for the port A and the port B is as described above.

In the embodiment and the modifications described above, an example in which the correction value calculated at the time of transfer is stored (updated) in the teaching position storage unit 7A (70A) without any change has been described, but the present invention is not limited thereto. For example, in a case where the area controller 70 (the transport vehicle controller 7) determines that a difference in distance between the teaching position P1 and the stop position P2 (difference in distance between the teaching position P1 and the stop position P2 in consideration of the correction value) does not fall within the predetermined range (that is, in a case where it is determined that calculating the correction value is necessary), a predetermined minute shift amount (for example, 1 mm) may be used as the correction value instead of the calculated correction value. The shift amount is set to a value smaller than the correction value to be calculated. According to such a modification, the control prevents a correction from being made that causes a large change in the teaching position P1 through a single transfer operation, that is, a large change in the amount of movement when the gripping part 6 descends at a high speed.

In the embodiment and modifications described above, an example in which the correction value is stored (updated) in the teaching position storage unit 7A (70A) every time the correction value is calculated for one transfer has been described, but the present invention is not limited thereto. For example, the area controller 70 (the transport vehicle controller 7) may calculate the correction value and cause the teaching position storage unit 7A (70A) to store (update) the correction value in a case where the number of times of determination as described above exceeds a prescribed number of times, instead of calculating the correction value immediately after the determination that the difference in distance between the teaching position P1 and the stop position P2 (the difference in distance between the teaching position P1 and the stop position P2 in consideration of the correction value) does not fall within the predetermined range. In the control according to such a modification, it is possible to update the correction value after confirming that the distance difference is a steady change.

In the embodiment and modifications described above, a case where a transfer is made to retrieve the FOUP 90 placed on the load port 102 has been described as an example. However, even when a transfer is made to place the FOUP 90 on the load port 102, the stop position P2 can be acquired. In other words, the above-described correction value can be calculated.

### REFERENCE SIGNS LIST

1 overhead transport vehicle (transport vehicle)
1A first vehicle (transport vehicle)
1B second vehicle (transport vehicle)
2 traveling part (main part)
3 lateral feeding part
4 turning part
5 lifting part
6 gripping part
7 transport vehicle controller (teaching position correction unit)
7A teaching position storage unit (storage unit)
20 flange detection unit (detection unit)
70 area controller (teaching position correction unit)
70A teaching position storage unit (storage unit)
80 overhead transport vehicle system
101 travel rail
102 load port (station)
P1 teaching position
P2 stop position (gripping position)

1. An overhead transport vehicle system comprising a plurality of transport vehicles for raising and lowering a gripping part configured to grip an article with respect to a main part traveling on a track supported by a ceiling by feeding out or winding in a belt connected to the gripping part, and transferring the article to and from a plurality of stations, wherein
each of the plurality of transport vehicles includes:
a lifting member configured to feed out or wind in the belt;
a detector provided in the gripping part, the detector configured to detect that the gripping part has reached a stop position at which to grip the article placed on one of the plurality of stations by detecting contact with the article placed on one of the plurality of stations;
a memory configured to store in advance, as a feed amount of the belt, a teaching position set such that a distance from the stop position falls within a predetermined range;
a transport vehicle control circuit configured to control an amount of elevation of the gripping part with respect to the main part based on the feed amount of the belt, control lowering of the gripping part at a first speed with respect to the main part, then control lowering of the gripping part at a second speed lower than the first speed from the teaching position, stop the gripping part when the detector detects that the gripping part has reached the stop position to thereby transfer the article to one of the transport vehicles, and acquire the feed amount of the belt at the stop position; and
a teaching position correction circuit configured to correct the feed amount of the teaching position belt stored for each of the plurality of stations based on an actual stop position of the gripping part at a time of transferring the article.

2. The overhead transport vehicle system according to claim 1, wherein the memory associates and stores the teaching positions for each of the plurality of stations, and
the teaching position correction circuit corrects the teaching position based on the stop position acquired for every transfer operation by the plurality of transport vehicles.

3. The overhead transport vehicle system according to claim 1, wherein the memory associates and stores the teaching position corresponding to each of the plurality of transport vehicles for each of the plurality of stations, and
the teaching position correction circuit is configured to the teaching position based on the stop position acquired by each of the transport vehicles for each of the plurality of stations.

4. The overhead transport vehicle system according to claim 3, wherein the memory is provided in each of the plurality of transport vehicles.

5. An overhead transport vehicle for raising and lowering a gripping part configured to grip an article with respect to a main part traveling on a track supported by a ceiling by feeding out or winding in a belt connected to the gripping part, and transferring the article to a plurality of stations, the overhead transport vehicle comprising:
a lifting member configured to feed out or wind in the belt;
a detector provided in the gripping part, the detector configured to detect that the gripping part has reached a stop position at which to grip the article placed on one of the plurality of stations by detecting contact with the article placed on one of the plurality of stations;
a memory configured to store in advance, as a feed amount of the belt, a teaching position set such that a distance from the stop position falls within a predetermined range;
a transport vehicle control circuit configured to control an amount of elevation of the gripping part with respect to the main part based on the feed amount of the belt, control lowering of the gripping part at a first speed with respect to the main part, then control lowering of the gripping part at a second speed lower than the first speed from the teaching position, stop the gripping part when the detector detects that the gripping part has reached the stop position to thereby transfer the article to the station, and acquire the feed amount of the belt at the stop position; and
a teaching position correction circuit configured to correct the teaching position stored for each of the stations based on an actual stop position of the gripping part at a time of transferring the article.
